(19) United States
(12) Patent Application Publication
(10) Pub. No.: US 2026/0372150 A1
(43) Pub. Date: Nov. 19, 2026

(54) INTERCONNECT SUBSTRATE

(71) Applicant: SHINKO ELECTRIC INDUSTRIES CO., LTD., Nagano (JP)

(72) Inventors: Masahiro SUNOHARA, Nagano (JP); Jun YOSHIIKE, Nagano (JP); Noriyoshi SHIMIZU, Nagano (JP)

(21) Appl. No.: 19/661,030

(22) Filed: Apr. 28, 2026

(30) Foreign Application Priority Data
May 15, 2025 (JP) 2025-081720

(51) Int. Cl. H10W 70/695; H10W 70/63; H10W 70/685; H10W 70/692

(52) U.S. Cl. CPC H10W 70/695; H10W 70/635; H10W 70/685; H10W 70/692

(57) ABSTRACT

An interconnect substrate includes a core layer made of glass, a first laminate including one or more interconnect layers and one or more insulating layers and disposed on an upper surface of the core layer, a second laminate including one or more interconnect layers and one or more insulating layers and disposed on a lower surface of the core layer, and a resin portion continuously covering, in cross-sectional view, a side surface of the core layer, a side surface of the first laminate, a side surface of the second laminate, a peripheral portion of an upper surface of the first laminate, and a peripheral portion of a lower surface of the second laminate.

### CROSS-REFERENCE TO RELATED APPLICATIONS

The present application is based on and claims priority to Japanese Patent Application No. 2025-081720 filed on May. 15, 2025, with the Japan Patent Office, the entire contents of which are incorporated herein by reference.

### FIELD

The disclosures herein generally relate to interconnect substrates.

### BACKGROUND

Interconnect substrates known in the art may each include interconnect layers and insulating layers laminated on the upper and lower surfaces of a core layer. A core layer made of glass may sometimes be used in an interconnect substrate. In this case, internal fractures may develop in the glass of the core layer. In consideration of this, for example, a resin portion serving as a protective film is provided on the side surfaces and the like of the core layer (Patent Document 1). However, a risk of delamination exists in the resin portion.

### RELATED-ART DOCUMENT

### Patent Document

### Patent Document 1 U.S. Patent Publication No. 2023/0087838

### SUMMARY

According to an aspect of the embodiment, an interconnect substrate includes a core layer made of glass, a first laminate including one or more interconnect layers and one or more insulating layers and disposed on an upper surface of the core layer, a second laminate including one or more interconnect layers and one or more insulating layers and disposed on a lower surface of the core layer, and a resin portion continuously covering, in cross-sectional view, a side surface of the core layer, a side surface of the first laminate, a side surface of the second laminate, a peripheral portion of an upper surface of the first laminate, and a peripheral portion of a lower surface of the second laminate.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A and 1B are drawings illustrating an example of an interconnect substrate according to a first embodiment;

FIG. 2 is a partial enlarged cross-sectional view of a resin portion and its vicinity illustrated in FIG. 1B;

FIG. 3 is a drawing illustrating an example of a manufacturing process of the interconnect substrate according to the first embodiment;

FIGS. 4A-4C are drawings illustrating the example of the manufacturing process of the interconnect substrate according to the first embodiment;

FIGS. 5A-5C are drawings illustrating the example of the manufacturing process of the interconnect substrate according to the first embodiment;

FIGS. 6A and 6B are drawings illustrating the example of the manufacturing process of the interconnect substrate according to the first embodiment;

FIG. 7 is a plan view illustrating an example of an interconnect substrate according to a first variation of the first embodiment; and

FIG. 8 is a plan view illustrating an example of an interconnect substrate according to the second variation of the first embodiment.

### DESCRIPTION OF EMBODIMENTS

Embodiments of the invention will be described below with reference to the accompanying drawings. In these drawings, the same components are denoted by the same reference numerals, and duplicate descriptions may be omitted.

### First Embodiment

### Structure of Interconnect Substrate of First Embodiment

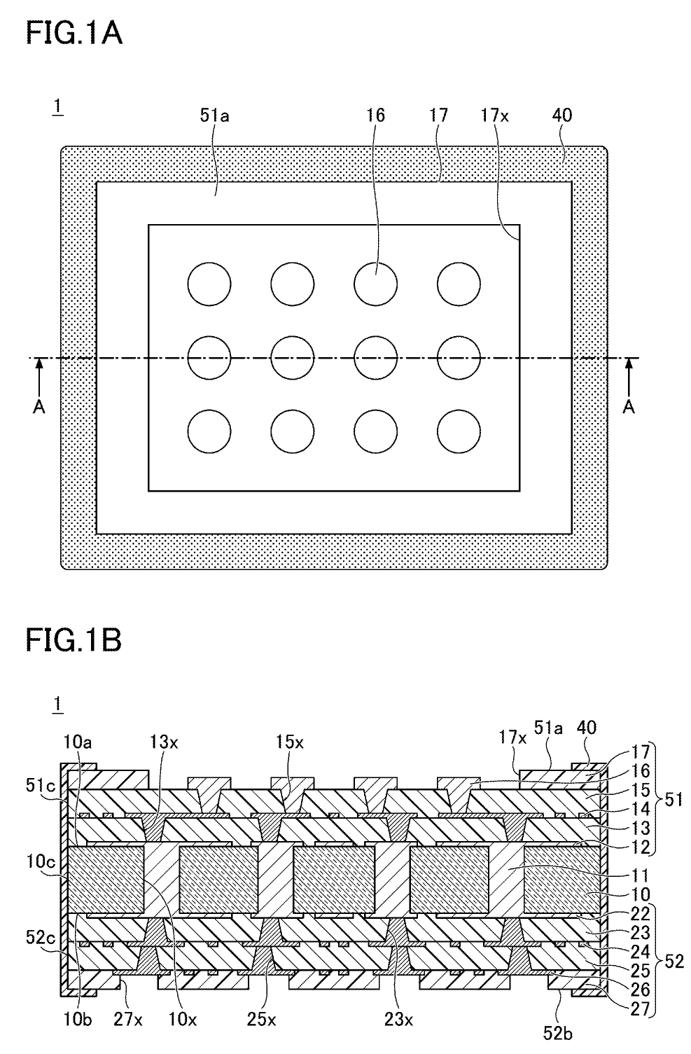

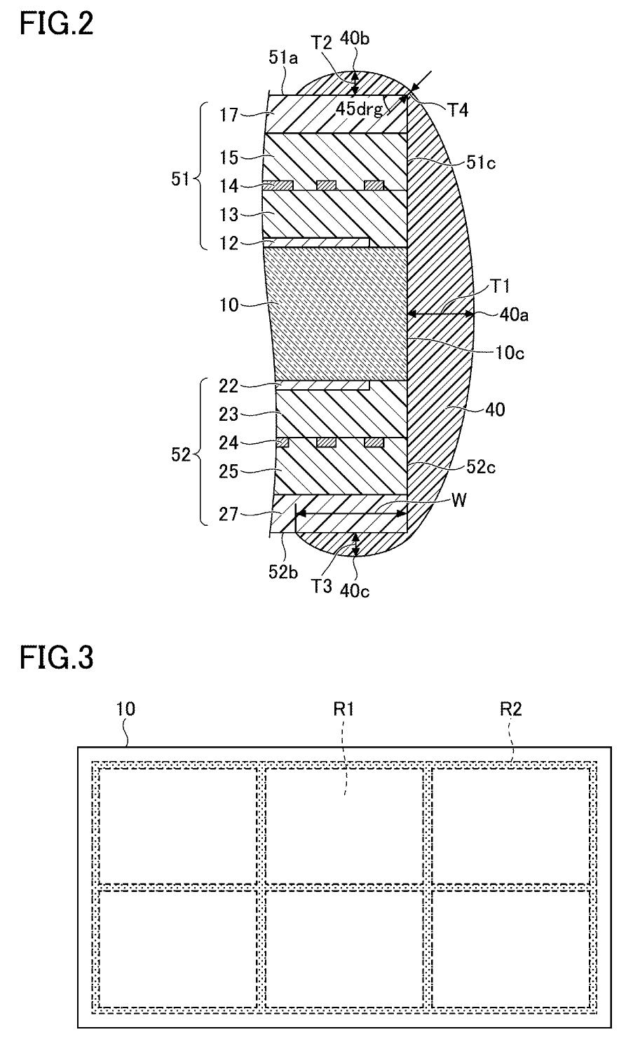

FIGS. 1A and 1B are drawings illustrating an example of an interconnect substrate according to a first embodiment. FIG. 1A is a plan view and FIG. 1B is a cross-sectional view taken along line A-A in FIG. 1A. FIG. 2 is a partial enlarged cross-sectional view of a resin portion and its vicinity illustrated in FIG. 1B.

Referring to FIGS. 1A and 1B and 2, an interconnect substrate 1 includes a core layer 10 having an upper surface 10a and a lower surface 10b opposite the upper surface 10a, a first laminate 51 including interconnect layers and insulating layers disposed on the upper surface 10a of the core layer 10, a second laminate 52 including interconnect layers and insulating layers disposed on the lower surface 10b of the core layer 10, and a resin portion 40. The interconnect substrate 1 may be formed to have a rectangular shape in plan view, for example.

The first laminate 51 includes an interconnect layer 12, an insulating layer 13, an interconnect layer 14, an insulating layer 15, an interconnect layer 16, and a solder resist layer 17 sequentially laminated on the upper surface 10a of the core layer 10. The second laminate 52 includes an interconnect layer 22, an insulating layer 23, an interconnect layer 24, an insulating layer 25, an interconnect layer 26, and a solder resist layer 27 sequentially laminated on the lower surface 10b of the core layer 10. The first laminate 51 and the second laminate 52 may each be formed to have a rectangular shape in plan view, for example.

In the first embodiment, for convenience, the solder resist layer 17 side of the interconnect substrate 1 is referred to as an upper side or a first side, and the solder resist layer 27 side is referred to as a lower side or a second side. The surface of a portion oriented in the same direction as the solder resist layer 17 side is referred to as a first surface or an upper surface, and the surface of a portion oriented in the same direction as the solder resist layer 27 side is referred to as a second surface or a lower surface. However, the interconnect substrate 1 may be positioned upside down when used, or may be arranged at any angle. The plan view refers to the view of an object as seen from the direction normal to the upper surface 10a of the core layer 10, and the plan shape refers to the shape of an object as seen from the direction normal to the upper surface 10a of the core layer 10.

The core layer 10 may be formed to have a rectangular shape in plan view, for example. The core layer 10 is made of glass. Although the kind of glass constituting the core layer 10 is not limited, alkali-free glass, quartz glass, borosilicate glass, or the like may be used, for example. The thickness of the core layer 10 is, for example, in the range of approximately 100 to 1000 μm. The core layer 10 has through holes 10x extending through the core layer 10 in the thickness direction. The plan shape of each of the through holes 10x is, for example, circular. The diameter of each of the through holes 10x may be, for example, from 100 μm to 500 μm.

A side surface 51c of the first laminate 51 is constituted by the side surface of the insulating layer 13, the side surface of the insulating layer 15, and the side surface of the solder resist layer 17. The side surface 51c of the first laminate 51 may or may not be perpendicular to the upper surface 10a of the core layer 10. The side surface 52c of the second laminate 52 is constituted by the side surface of the insulating layer 23, the side surface of the insulating layer 25, and the side surface of the solder resist layer 27. A side surface 52c of the second laminate 52 may or may not be perpendicular to the lower surface 10b of the core layer 10. The side surface 51c of the first laminate 51 and the side surface 52c of the second laminate 52 are flush with a side surface 10c of the core layer 10, for example.

The resin portion 40 continuously covers the side surface 10c of the core layer 10, the side surface 51c of the first laminate 51, the side surface 52c of the second laminate 52, a peripheral portion of the upper surface 51a of the first laminate 51, and a peripheral portion of the lower surface 52b of the second laminate 52. However, the resin portion 40 may partially have a discontinuous portion (i.e., gap) caused by uneven coating or the like generated during the formation of the resin portion 40. The upper surface 51a of the first laminate 51 is the upper surface of the solder resist layer 17, and the lower surface 52b of the second laminate 52 is the lower surface of the solder resist layer 27.

The core layer 10, the first laminate 51, and the second laminate 52 each have a plurality of corners in plan view. The resin portion 40 covers the side surfaces 10c of the core layer 10, the side surfaces 51c of the first laminate 51, the side surfaces 52c of the second laminate 52, the peripheral portion of the upper surface 51a of the first laminate 51, and the peripheral portion of the lower surface 52b of the second laminate 52, at least along each corner in plan view. The resin portion 40 may be, for example, an epoxy-based resin or an acrylic-based resin. The resin portion 40 may be a thermosetting resin or an ultraviolet curing resin.

In the example illustrated in FIGS. 1A and 1B, the core layer 10, the first laminate 51, and the second laminate 52 are each square or rectangular in plan view and each have four corners. In the example illustrated in FIGS. 1A and 1B, the resin portion 40 covers, in a closed-loop shape including the four corners, the side surfaces 10c of the core layer 10, the side surfaces 51c of the first laminate 51, the side surfaces 52c of the second laminate 52, the peripheral portion of the upper surface 51a of the first laminate 51, and the peripheral portion of the lower surface 52b of the second laminate 52 in plan view. The resin portion 40 is, for example, frame-shaped in plan view.

In this manner, the resin portion 40 covers the side surfaces 10c of the core layer 10, the side surfaces 51c of the first laminate 51, and the side surfaces 52c of the second laminate 52. This arrangement effectively reduces internal fractures in the glass of the core layer 10. This will be described in detail below.

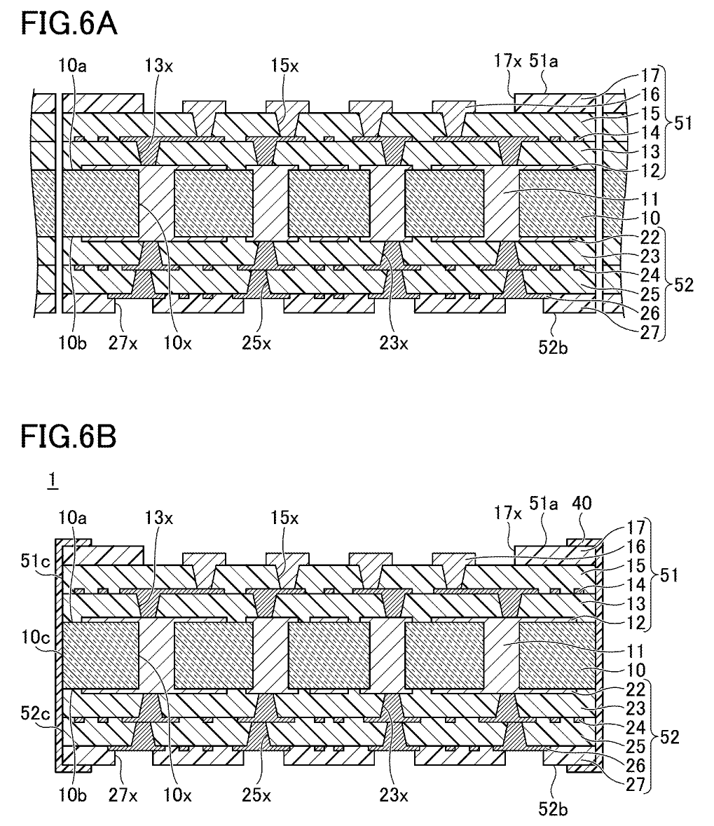

The manufacturing process of the interconnect substrate 1 involves singulation into each interconnect substrate 1 (for example, see FIG. 6A, which will be described later). During the singulation of the interconnect substrate 1, microcracks may develop in the vicinity of the cut surface. The presence of microcracks may cause cracking of the core layer 10 made of glass. In particular, when the singulated interconnect substrate 1 is heated, cracks may propagate deep into the core layer 10 starting from the microcracks in the vicinity of the cut surface, resulting in internal fracture of the core layer 10. The interconnect substrate 1 is heated, for example, when a semiconductor chip is mounted on the interconnect substrate 1 and soldered by reflow soldering. The mechanism that causes internal fracture during heating may be explained as follows.

Generally, an interconnect substrate is such that the glass core layer, the interconnect layers, and the insulating layers have different coefficients of thermal expansion. For example, the thermal expansion coefficient of a glass core layer is in the range of approximately 3 to 15 ppm/°C, and the thermal expansion coefficient of interconnect layers made of copper is about 17 ppm/°C. The thermal expansion coefficient of insulating layers made of resin is in the range of approximately 10 to 100 ppm/°C. As a result, an increase in the temperature of the interconnect substrate due to heating generates thermal contraction force at the center region of the interconnect substrate, causing tensile stress in the vertical direction and the concentration of the stress at the periphery of the glass core layer. The strength of the glass may be insufficient, and internal fracture may occur, originating at the periphery.

The most likely originating points are the interface between the core layer 10 and the insulating layer 13, and the interface between the core layer 10 and the insulating layer 23. In consideration of this, the resin portion 40 is provided to cover and protect these interfaces as well as the side surfaces 10c of the core layer 10, the side surfaces 51c of the first laminate 51, and the side surfaces 52c of the second laminate 52. As a result, even during the heating of the singulated interconnect substrate 1, internal fracture in the glass of the core layer 10 is suppressed, which effectively improves the reliability of the interconnect substrate 1.

In addition, the resin portion 40 covers the peripheral portion of the upper surface 51a of the first laminate 51 and the peripheral portion of the lower surface 52b of the second laminate 52, in addition to the side surfaces 10c of the core layer 10, the side surfaces 51c of the first laminate 51, and the side surfaces 52c of the second laminate 52. This arrangement effectively suppresses delamination of the resin portion 40 from the core layer 10, the first laminate 51, and the second laminate 52. In addition, the rigidity of the interconnect substrate 1 is effectively increased. The width W of the resin portion 40 covering the peripheral portion of the upper surface 51a of the first laminate 51 and the peripheral portion of the lower surface 52b of the second laminate 52 may be, for example, from 10 μm to 1000 μm.

As illustrated in FIG. 2, in cross-sectional view, the resin portion 40 covering the side surface 10c of the core layer 10, the side surface 51c of the first laminate 51, and the side surface 52c of the second laminate 52 preferably has a first thickest portion 40a in the region covering the side surface 10c of the core layer 10. Preferably, the resin portion 40 around this region has a convex profile in which the thickness gradually decreases from the first thickest portion 40a toward the upper end of the side surface 51c of the first laminate 51 and the lower end of the side surface 52c of the second laminate 52. This arrangement effectively reduces stress concentration at any specific point of the resin portion 40 covering the side surface 10c of the core layer 10, the side surface 51c of the first laminate 51, and the side surface 52c of the second laminate 52. The thickness T1 of the first thickest portion 40a is, for example, from 10 μm to 1000 μm. The thickness T1 is measured in the direction perpendicular to the side surface 10c of the core layer 10.

In a cross-sectional view, the resin portion 40 covering the peripheral portion of the upper surface 51a of the first laminate 51 preferably has a second thickest portion 40b. The resin portion 40 in this region preferably has a convex profile in which the thickness gradually decreases from the second thickest portion 40b toward the outer edge of the upper surface 51a of the first laminate 51 and the side opposite the outer edge of the upper surface 51a. This arrangement effectively reduces stress concentration at any specific point of the resin portion 40 covering the peripheral portion of the upper surface 51a of the first laminate 51. The thickness T2 of the second thickest portion 40b is, for example, from 5 μm to 500 μm. The thickness T2 is measured in the direction perpendicular to the upper surface 51a of the first laminate 51.

In a cross-sectional view, the resin portion 40 covering the peripheral portion of the lower surface 52b of the second laminate 52 preferably has a third thickest portion 40c. The resin portion 40 in this region preferably has a convex profile in which the thickness gradually decreases from the third thickest portion 40c toward the outer edge of the lower surface 52b of the second laminate 52 and the side opposite the outer edge of the lower surface 52b. This effectively reduces stress concentration at any specific point of the resin portion 40 covering the peripheral portion of the lower surface 52b of the second laminate 52. The thickness T3 of the third thickest portion 40c is, for example, from 5 μm to 500 μm. The thickness T3 is measured in the direction perpendicular to the lower surface 52b of the second laminate 52.

The thickness T1 of the first thickest portion 40a is preferably greater than the thickness T2 of the second thickest portion 40b and the thickness T3 of the third thickest portion 40c. Increasing the thickness T1 of the first thickest portion 40a facilitates reducing internal fractures in the glass of the core layer 10. In addition, decreasing the thickness T2 of the second thickest portion 40b and the thickness T3 of the third thickest portion 40c facilitates mounting components on the first laminate 51 and the second laminate 52.

The first laminate 51 and the second laminate 52 each have corners in cross-sectional view. With respect to the first laminate 51, the connection point between the upper surface 51a and the side surface 51c is a corner in cross-sectional view. With respect to the second laminate 52, the connection point between the lower surface 52b and the side surface 52c is a corner in cross-sectional view. The resin portion 40 preferably covers the corners of the first laminate 51 and the second laminate 52. Covering the corners with the resin portion 40 effectively improves the reliability of the interconnect substrate 1. The thickness T4 of the resin portion 40 at the corners is preferably thin from the viewpoint of preventing cracks or the like from occurring in the resin portion 40. The thickness T4 is, for example, greater than 0 and at most 1/4 of the thickness T1. The thickness T4 may be greater than 0 and at most 1/5 of the thickness T1. The thickness T4 is measured at an angle of 135 ° clockwise from the upper surface 51a at the connection point between the upper surface 51a and the side surface 51c, or measured at an angle of 135 ° counterclockwise from the lower surface 52b at the connection point between the lower surface 52b and the side surface 52c.

The interconnect layer 12 is disposed on the upper surface 10a of the core layer 10. The interconnect layer 22 is disposed on the lower surface 10b of the core layer 10. The interconnect layer 12 and the interconnect layer 22 are electrically connected by through interconnects 11 formed in the through holes 10x. Each of the interconnect layers 12 and 22 is patterned in a predetermined plan shape. The interconnect layers 12 and 22 and the through interconnects 11 may be made of, for example, copper (Cu). The thicknesses of the interconnect layers 12 and 22 are, for example, in the range of approximately 10 to 40 μm. The interconnect layer 12, the interconnect layer 22, and the through interconnects 11 may be seamlessly formed.

The insulating layer 13 is an interlayer insulating layer disposed on the upper surface 10a of the core layer 10 and covering the interconnect layer 12. The material of the insulating layer 13 may be, for example, an insulating resin or the like mainly composed of an epoxy-based resin or a polyimide-based resin. The thickness of the insulating layer 13 may be, for example, in the range of approximately 20 to 40 μm. The insulating layer 13 may contain a filler such as silica (SiO₂).

Via holes 13x are formed in the insulating layer 13 to extend through the insulating layer 13 and reach the upper surface of the interconnect layer 12. The via holes 13x may each be an inverted truncated conical hole in which the diameter of the opening toward the insulating layer 15 is larger than the diameter of the opening at the upper surface of the interconnect layer 12.

The interconnect layer 14 is formed on the first side of the insulating layer 13. The interconnect layer 14 includes via interconnects filling the via holes 13x and an interconnect pattern formed on the upper surface of the insulating layer 13. The interconnect pattern is electrically connected to the interconnect layer 12 via the via interconnects. The material of the interconnect layer 14 and the thickness of the interconnect pattern may be substantially the same as those of the interconnect layer 12, for example.

The insulating layer 15 is formed on the upper surface of the insulating layer 13 so as to cover the interconnect layer 14. The material and the thickness of the insulating layer 15 may be substantially the same as those of the insulating layer 13, for example. The insulating layer 15 may contain a filler such as silica (SiO₂).

Via holes 15x are formed in the insulating layer 15 to extend through the insulating layer 15 and reach the upper surface of the interconnect layer 14. The via holes 15x may each be an inverted truncated conical hole in which the diameter of the opening toward the solder resist layer 17 is larger than the diameter of the opening at the upper surface of the interconnect layer 14.

The interconnect layer 16 is formed on the first side of the insulating layer 15. The interconnect layer 16 includes via interconnects filling the via holes 15x and pads formed on the upper surface of the insulating layer 15. The pads are electrically connected to the interconnect layer 14 through the via interconnects. The material of the interconnect layer 16 and the thickness of the pads may be substantially the same as those of the interconnect layer 12, for example. The thickness of the pads may be larger than that of the interconnect layer 12. The interconnect layer 16 may also include an interconnect pattern in addition to the pads.

The solder resist layer 17 is a protective insulating layer located as the outermost layer on the first side of the interconnect substrate 1 and is formed on the upper surface of the insulating layer 15 while leaving the interconnect layer 16 exposed. The solder resist layer 17 may be formed in a closed-loop configuration to leave the interconnect layer 16 exposed in an opening 17x, for example. The pads of the interconnect layer 16 exposed in the opening 17x may be used for electrical connections with an electronic component such as a semiconductor chip, for example. The solder resist layer 17 may be formed of, for example, a photosensitive epoxy-based insulating resin or acrylic-based insulating resin. The thickness of the solder resist layer 17 is, for example, in the range of approximately 15 to 35 μm.

On the surface of the interconnect layer 16 exposed in the opening 17x, a metal layer may be formed or an organic film may be formed by performing an oxidation prevention treatment such as OSP (Organic Solderability Preservative) treatment. Examples of the metal layer include an Au layer, a Ni/Au layer (a metal layer formed by laminating a Ni layer and an Au layer in this order), a Ni/Pd/Au layer (a metal layer formed by laminating a Ni layer, a Pd layer, and an Au layer in this order), and a Sn layer.

The insulating layer 23 is an interlayer insulating layer disposed on the lower surface 10b of the core layer 10 and covering the interconnect layer 22. The material and the thickness of the insulating layer 23 may be substantially the same as those of the insulating layer 13, for example. The insulating layer 23 may contain a filler such as silica (SiO₂).

Via holes 23x are formed in the insulating layer 23 to extend through the insulating layer 23 and reach the lower surface of the interconnect layer 22. The via holes 23x may each be a truncated conical hole in which the diameter of the opening toward the insulating layer 25 is larger than the diameter of the opening at the lower surface of the interconnect layer 22.

The interconnect layer 24 is formed on the second side of the insulating layer 23. The interconnect layer 24 includes via interconnects filling the via holes 23x and an interconnect pattern formed on the lower surface of the insulating layer 23. The interconnect pattern is electrically connected to the interconnect layer 22 through the via interconnects. The material and thickness of the interconnect layer 24 may be substantially the same as those of the interconnect layer 12, for example.

The insulating layer 25 is formed so as to cover the interconnect layer 24 on the lower surface of the insulating layer 23. The material and thickness of the insulating layer 25 may be substantially the same as those of the insulating layer 13, for example. The insulating layer 25 may contain a filler such as silica (SiO₂).

Via holes 25x are formed in the insulating layer 25 to extend through the insulating layer 25 and reach the lower surface of the interconnect layer 24. The via holes 25x may each be a truncated conical hole in which the diameter of the opening toward the solder resist layer 27 is larger than the diameter of the opening at the lower surface of the interconnect layer 24.

The interconnect layer 26 is formed on the second side of the insulating layer 25. The interconnect layer 26 includes via interconnects filling the via holes 25x and an interconnect pattern formed on the lower surface of the insulating layer 25. The interconnect pattern is electrically connected to the interconnect layer 24 through the via interconnects. The material and the thickness of the interconnect layer 26 may be substantially the same as those of the interconnect layer 12, for example.

The solder resist layer 27 is a protective insulating layer located as the outermost layer on the second side of the interconnect substrate 1, and is formed on the lower surface of the insulating layer 25 to cover the interconnect layer 26. The material and thickness of the solder resist layer 27 may be substantially the same as those of the solder resist layer 17, for example. The solder resist layer 27 has openings 27x, and portions of the lower surface of the interconnect layer 26 are exposed within the openings 27x. The plan shape of each of the openings 27x may be, for example, circular. The interconnect layer 26 exposed in the openings 27x may be used as pads for electrical connections to a mounting substrate such as a motherboard. If necessary, a metal layer of the kind previously described may be formed on the lower surface of the interconnect layer 26 exposed in the openings 27x, or an oxidation prevention treatment such as OSP treatment may be applied.

### Method of Making Interconnect Substrate

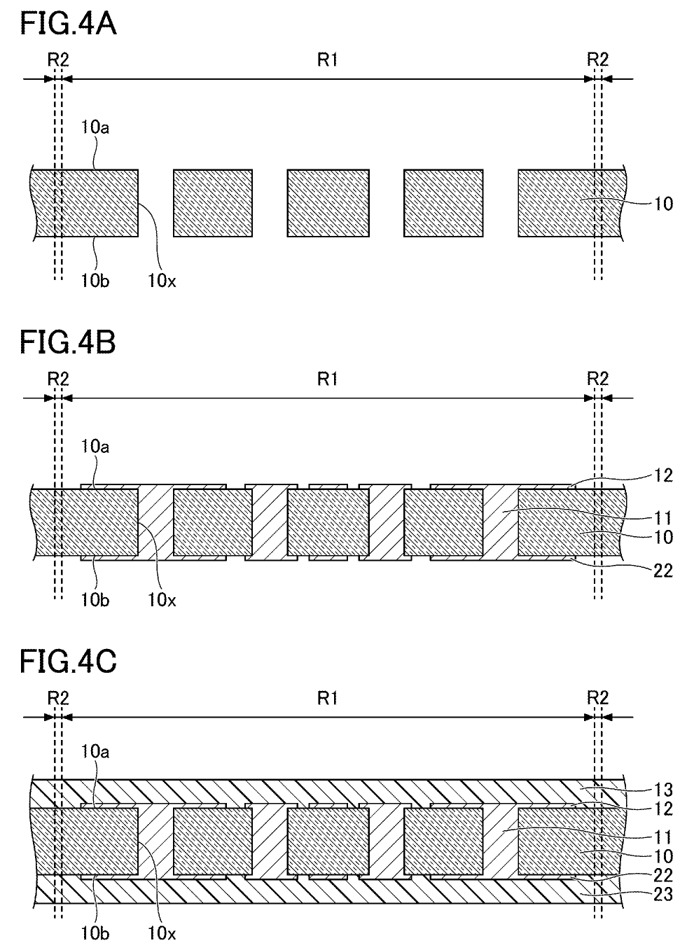

FIGS. 3-6A and 6B are drawings illustrating an example of a manufacturing process of the interconnect substrate according to the first embodiment. FIG. 3 is a plan view, and FIGS. 4A-4C-6A and 6B are cross-sectional views.

First, in the step illustrated in FIG. 3, a glass core layer 10 is prepared. The core layer 10 includes a plurality of interconnect regions R1 that are to be singulated to form interconnect substrates, and a cutting region R2 along which a cut is made for singulation. FIG. 3 depicts the cutting region R2 in dot shading for convenience.

In the step illustrated in FIG. 4A, through holes 10x are formed in each interconnect region R1 of the core layer 10 by wet etching. Examples of the etching solution include hydrofluoric acid, a strong alkaline solution, and the like.

In the step illustrated in FIG. 4B, an interconnect layer 12 is disposed in each interconnect region R1 on the upper surface 10a of the core layer 10, and an interconnect layer 22 is disposed in each interconnect region R1 on the lower surface 10b of the core layer 10, with through interconnects 11 formed in the through holes 10x. For example, a seed layer (copper or the like) covering the upper surface 10a, the lower surface 10b, and the inner wall surfaces of the through holes 10x of the core layer 10 is formed by electroless plating, sputtering, or the like, followed by forming an electrolytic plating layer (copper or the like) on the seed layer by electrolytic plating using the seed layer as a path to feed current. This arrangement fills the through holes 10x with the electrolytic plating layer formed on the seed layer, and forms the interconnect layers 12 and 22 each as a laminate of the seed layer and the electrolytic plating layer on the upper surface 10a and the lower surface 10b, respectively, of the core layer 10. Thereafter, the interconnect layers 12 and 22 are each patterned into a predetermined plan shape by a subtractive method or the like.

In the step illustrated in FIG. 4C, an insulating layer 13 covering the interconnect layer 12 is disposed in each interconnect region R1 and the cutting region R2 on the upper surface 10a of the core layer 10. Specifically, for example, a semi-cured epoxy-based resin film or the like is laminated on the upper surface 10a of the core layer 10 so as to cover the interconnect layer 12, and then cured to form the insulating layer 13. Alternatively, instead of laminating epoxy-based resin film or the like, epoxy-based resin or the like in liquid or paste form may be applied and then cured to form the insulating layer 13. The material and the thickness of the insulating layer 13 are as previously described. Similarly, an insulating layer 23 covering the interconnect layer 22 is disposed in each interconnect region R1 and the cutting region R2 on the lower surface 10b of the core layer 10.

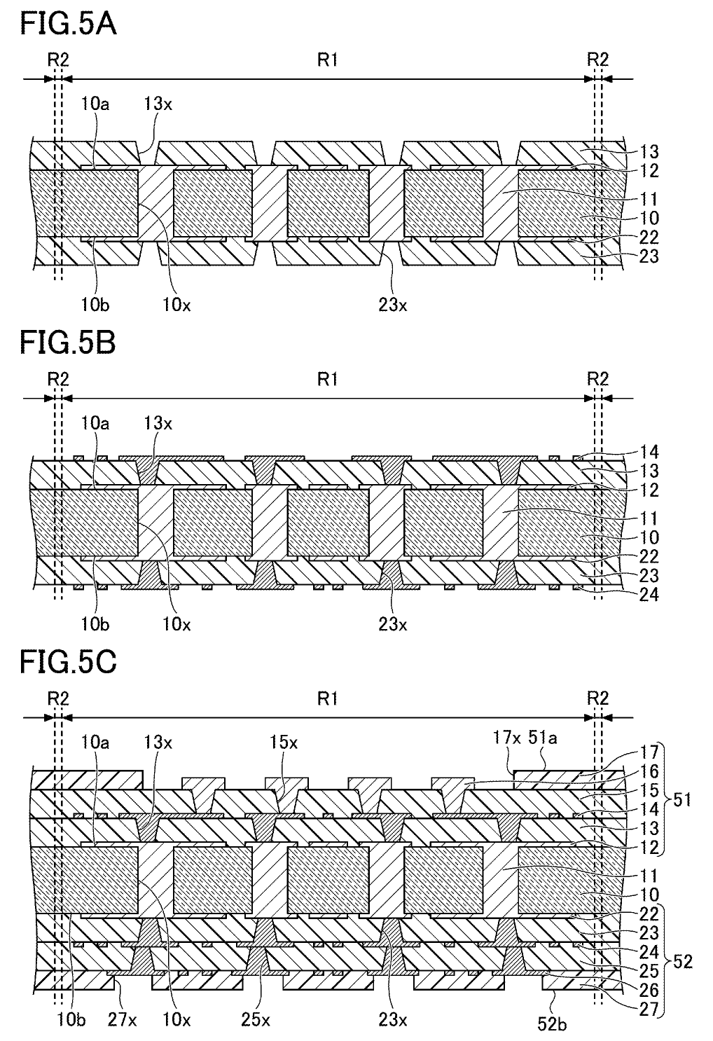

In the step illustrated in FIG. 5A, via holes 13x are formed in the insulating layer 13 to penetrate the insulating layer 13 and expose the upper surface of the interconnect layer 12. Further, via holes 23x are formed in the insulating layer 23 to penetrate the insulating layer 23 and expose the lower surface of the interconnect layer 22. The via holes 13x and 23x may be formed, for example, by laser processing using a CO₂ laser or the like. After the via holes 13x and 23x are formed, desmearing is preferably performed to remove resin residues adhering to the surfaces of the interconnect layers 12 and 22 exposed at the end of the via holes 13x and 23x.

In the step illustrated in FIG. 5B, an interconnect layer 14 is formed on the first side of the insulating layer 13. The interconnect layer 14 includes via interconnects filling the via holes 13x and an interconnect pattern formed on the upper surface of the insulating layer 13. The interconnect layer 14 is electrically connected to the interconnect layer 12 exposed at the bottom of the via holes 13x. Similarly, an interconnect layer 24 is formed on the second side of the insulating layer 23. The interconnect layer 24 includes via interconnects filling the via holes 23x and an interconnect pattern formed on the lower surface of the insulating layer 23. The interconnect layer 24 is electrically connected to the interconnect layer 22 exposed at the end of the via holes 23x. The materials of the interconnect layers 14 and 24 and the thicknesses of the interconnect patterns may be substantially the same as those of the interconnect layer 12, for example.

In the step illustrated in FIG. 5C, first, substantially the same steps as those in FIGS. 4C-5B are repeated to form insulating layers 15 and 25 and interconnect layers 16 and 26. Thereafter, a solder resist layer 17 is formed on the upper surface of the insulating layer 15 so as to cover the interconnect layer 16. Further, a solder resist layer 27 is formed on the lower surface of the insulating layer 25 so as to cover the interconnect layer 26. The solder resist layer 17 may be formed, for example, by applying a photosensitive epoxy-based insulating resin in liquid or paste form to the upper surface of the insulating layer 15 so as to cover the interconnect layer 16 by screen printing, roll coating, spin coating, or the like. Alternatively, a photosensitive epoxy-based insulating resin film, for example, may be laminated on the upper surface of the insulating layer 15 so as to cover the interconnect layer 16. The method of forming the solder resist layer 27 is substantially the same as that of the solder resist layer 17. Thereafter, the solder resist layers 17 and 27 are exposed and developed. As a result, an opening 17x is formed through the solder resist layer 17 to expose the interconnect layer 16. Also, openings 27x for exposing portions of the lower surface of the interconnect layer 26 are formed in the solder resist layer 27. Through these steps, the first laminate 51 and the second laminate 52 are fabricated.

Next, in the step illustrated in FIG. 6A, the structure illustrated in FIG. 5C is cut along the cutting region R2 for singulation into a plurality of structures each having the core layer 10, the first laminate 51, and the second laminate 52. The cutting may be performed by, for example, a dicing blade. The cutting may alternatively be performed by laser irradiation or the like.

In the step illustrated in FIG. 6B, a resin portion 40 is formed on each of the singulated structures. The resin portion 40 is formed so as to continuously cover the side surface 10c of the core layer 10, the side surface 51c of the first laminate 51, the side surface 52c of the second laminate 52, a peripheral portion of the upper surface 51a of the first laminate 51, and a peripheral portion of the lower surface 52b of the second laminate 52. The resin portion 40 may be formed by, for example, applying an uncured resin to the target areas using a coating apparatus having a syringe filled with an uncured resin, followed by curing the applied resin. Alternatively, the resin portion 40 may be formed by applying an uncured resin to the target areas using a coating apparatus having a roller impregnated with an uncured resin, followed by curing the applied resin. These coating apparatuses are capable of controlling the thickness of the resin portion 40 and may thus effectively form, for example, the resin portion 40 having the shape illustrated in FIG. 2. By following these steps, the manufacture of the interconnect substrate 1 is achieved.

### Variations of First Embodiment

Variations of the first embodiment are directed to examples in which the positions of the resin portion 40 are different from those in the interconnect substrate of the first embodiment. In connection with the variations of the first embodiment, descriptions of the same components as those of the already described embodiment may be omitted.

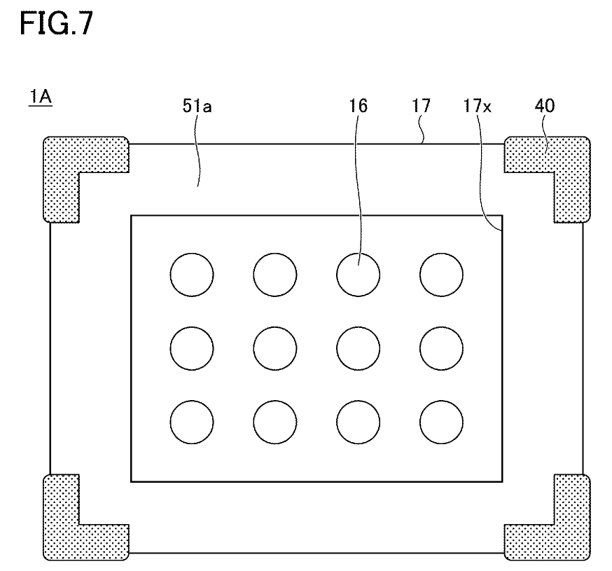

FIG. 7 is a plan view illustrating an example of an interconnect substrate according to a first variation of the first embodiment. An interconnect substrate 1A illustrated in FIG. 7 is configured such that, in plan view, resin portions 40 are separated from each other and each bent along a corresponding one of the four corners of the core layer 10, the first laminate 51, and the second laminate 52. That is, the number of corners and the number of resin portions 40 are the same.

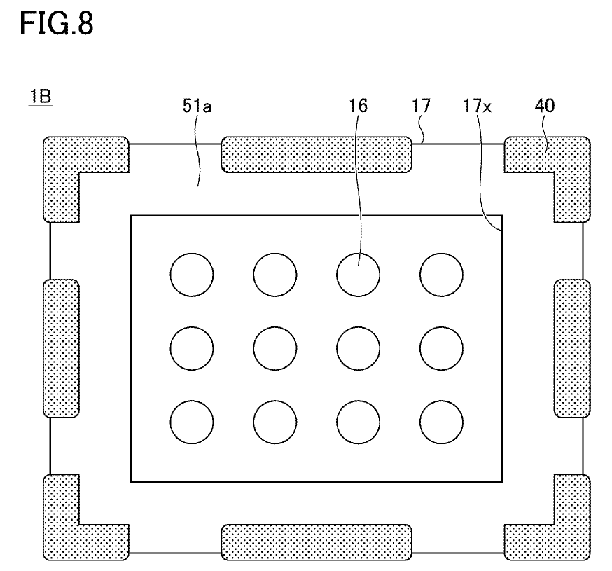

FIG. 8 is a plan view illustrating an example of an interconnect substrate according to the second variation of the first embodiment. An interconnect substrate 1B illustrated in FIG. 8 is configured such that resin portions 40 include those provided at the same positions as in the interconnect substrate 1A and those provided between adjacent corners. In the interconnect substrate 1B, eight resin portions 40 spaced apart from each other are provided. The number of resin portions 40 spaced apart from each other may be greater.

As illustrated in FIGS. 7 and 8, it suffices for the resin portion 40 to include at least the portions that are bent along the four corners of the core layer 10, the first laminate 51, and the second laminate 52 in plan view. That is, the resin portion 40 need not be provided in a closed-loop shape to cover the side surfaces 10c of the core layer 10, the side surfaces 51c of the first laminate 51, the side surfaces 52c of the second laminate 52, the peripheral portion of the upper surface 51a of the first laminate 51, and the peripheral portion of the lower surface 52b of the second laminate 52 in plan view, as in the first embodiment. Stress tends to concentrate on each corner of the core layer 10, the first laminate 51, and the second laminate 52 when the temperature rises. Therefore, providing the resin portion 40 including at least the portions that are bent along the perimeters of the respective corners in plan view effectively suppresses internal fracture in the core layer 10 made of glass.

According to at least one embodiment, an interconnect substrate having a core layer made of glass is provided that effectively reduces delamination of a resin portion covering the side surfaces and the like of the core layer.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. An interconnect substrate comprising:
a core layer made of glass;
a first laminate including one or more interconnect layers and one or more insulating layers and disposed on an upper surface of the core layer;
a second laminate including one or more interconnect layers and one or more insulating layers and disposed on a lower surface of the core layer; and
a resin portion continuously covering, in cross-sectional view, a side surface of the core layer, a side surface of the first laminate, a side surface of the second laminate, a peripheral portion of an upper surface of the first laminate, and a peripheral portion of a lower surface of the second laminate.

2. The interconnect substrate according to claim 1, wherein the core layer, the first laminate, and the second laminate have a plurality of corners in plan view, and the resin portion covers, at least along the plurality of corners in plan view, the side surface of the core layer, the side surface of the first laminate, the side surface of the second laminate, the peripheral portion of the upper surface of the first laminate, and the peripheral portion of the lower surface of the second laminate.

3. The interconnect substrate according to claim 1, wherein the resin portion covers, in a closed-loop shape in plan view, the side surface of the core layer, the side surface of the first laminate, the side surface of the second laminate, the peripheral portion of the upper surface of the first laminate, and the peripheral portion of the lower surface of the second laminate.

4. The interconnect substrate according to claim 1, wherein in cross-sectional view, the resin portion covering the side surface of the core layer, the side surface of the first laminate, and the side surface of the second laminate has a first thickest portion in a region covering the side surface of the core layer, and a thickness of the resin portion gradually decreases from the first thickest portion toward an upper end of the side surface of the first laminate and a lower end of the side surface of the second laminate.

5. The interconnect substrate according to claim 4, wherein in cross-sectional view, the resin portion on the peripheral portion of the upper surface of the first laminate has a second thickest portion, and a thickness of the resin portion gradually decreases from the second thickest portion toward an outer edge of the upper surface of the first laminate and a side opposite the outer edge of the upper surface.

6. The interconnect substrate according to claim 5, wherein in cross-sectional view, the resin portion on the peripheral portion of the lower surface of the second laminate has a third thickest portion, and a thickness of the resin portion gradually decreases from the third thickest portion toward an outer edge of the lower surface of the second laminate and a side opposite the outer edge of the lower surface.

7. The interconnect substrate according to claim 6, wherein the first thickest portion is thicker than the second thickest portion and the third thickest portion.

8. The interconnect substrate according to claim 7, wherein the first laminate and the second laminate have corners in cross-sectional view, and the resin portion covers each of the corners.

9. The interconnect substrate according to claim 1, further comprising a through interconnect extending through the core layer, wherein the one or more interconnect layers and the one or more insulating layers of the first laminate include a plurality of first interconnect layers and a plurality of first insulating layers alternately laminated, and the one or more interconnect layers and the one or more insulating layers of the second laminate include a plurality of second interconnect layers and a plurality of second insulating layers alternately laminated, and
wherein the through interconnect electrically connects one of the first interconnect layers and one of the second interconnect layers.

10. The interconnect substrate according to claim 1, wherein the side surface of the first laminate and the side surface of the second laminate are flush with the side surface of the core layer.

11. The interconnect substrate according to claim 1, wherein a width of the resin portion covering the peripheral portion of the upper surface of the first laminate and a width of the resin portion covering the peripheral portion of the lower surface of the second laminate are each from 10 μm to 1000 μm.

12. The interconnect substrate according to claim 4, wherein a thickness of the first thickest portion is from 10 μm to 1000 μm.

13. The interconnect substrate according to claim 5, wherein a thickness of the second thickest portion is from 5 μm to 500 μm.
